(19) United States
(12) Patent Application Publication
(10) Pub. No.: US 2025/0210356 A1
(43) Pub. Date: Jun. 26, 2025

(54) GATE TERMINAL METHODS AND STRUCTURES

(71) Applicants: Zafrullah JAGOO, Aloha, OR (US); Harish GANAPATHY, Portland, OR (US); Kishore Kumar KOMIRISETTY, Hillsboro, OR (US); Pranav SHARMA, Beaverton, OR (US); Tongtawee WACHARASINDHU, Hillsboro, OR (US); Han WANG, Portland, OR (US); Xiaoye QIN, Portland, OR (US); Andre BARAN, Portland, OR (US); David TOWNER, Portland, OR (US); Jacob JENSEN, Beaverton, OR (US); Orb ACTON, Portland, OR (US); Robert JAMES, Portland, OR (US)

(72) Inventors: Zafrullah JAGOO, Aloha, OR (US); Harish GANAPATHY, Portland, OR (US); Kishore Kumar KOMIRISETTY, Hillsboro, OR (US); Pranav SHARMA, Beaverton, OR (US); Tongtawee WACHARASINDHU, Hillsboro, OR (US); Han WANG, Portland, OR (US); Xiaoye QIN, Portland, OR (US); Andre BARAN, Portland, OR (US); David TOWNER, Portland, OR (US); Jacob JENSEN, Beaverton, OR (US); Orb ACTON, Portland, OR (US); Robert JAMES, Portland, OR (US)

(21) Appl. No.: 18/393,442

(22) Filed: Dec. 21, 2023

(51) Int. Cl. H01L 21/28; H01L 29/49

(52) U.S. Cl. CPC H01L 21/28088; H10D 64/667

(57) ABSTRACT

In some embodiments, the strength of the work function (WF) for P-type MOS transistors may be boosted by doping a gate layer surface using a plasma oxidation treatment after a metallic nitride (e.g., MoN film) has been deposited.

### TECHNICAL FIELD

Embodiments of the invention relate to the field of semiconductor manufacturing; and more specifically, to the manufacture of transistor features.

### BRIEF DESCRIPTION OF THE DRAWINGS

The disclosure may best be understood by referring to the following description and accompanying drawings that are used to illustrate embodiments of the invention. In the drawings:

FIG. 1 is a graph showing a relationship between WF and gate material thickness for a PMOS example.

FIG. 2A is a flow diagram showing a process for generating a PMOS transistor gate with an enhanced work function in accordance with some embodiments.

FIGS. 2B-2D are cross-sectional schematic diagrams illustrating a formed gate at different process stages in accordance with some embodiments.

FIG. 2E is a graph showing a relationship between WF and gate material thickness for a PMOS transistor with a plasma oxidized gate in accordance with some embodiments.

FIG. 3A is a perspective view of a FinFET transistor structure using a WF enhanced gate terminal in accordance with some embodiments.

FIG. 3B is a cross-sectional diagram showing a gate structure for the FinFET of FIG. 3A in accordance with some embodiments.

FIG. 4A is a perspective view of a GAA nanowire transistor structure using a WF enhanced gate terminal in accordance with some embodiments.

FIG. 4B is a cross-sectional diagram showing a gate structure for the GAA nanowire transistor of FIG. 4A in accordance with some embodiments.

FIG. 5A is a perspective view of a GAA nanosheet transistor structure using a WF enhanced gate terminal in accordance with some embodiments.

FIG. 5B is a cross-sectional diagram showing a gate structure for the GAA nanosheet transistor of FIG. 5A in accordance with some embodiments.

FIG. 6 illustrates an example computing system in accordance with some embodiments.

FIG. 7 is a block diagram of an example processor and/or SoC for use with the system of FIG. 6 that may have one or more cores and an integrated memory controller in accordance with some embodiments.

### DETAILED DESCRIPTION

In some embodiments, the strength of the work function (WF) for P-type MOS transistors may be boosted by doping a gate layer surface using a plasma oxidation treatment after a metallic nitride (e.g., MoN film) has been deposited. In some cases, there may be at least a 50 mV VFB (applied voltage at the flat band) gain. A way is provided to boost the transistor work function without having to incur an effective dielectric thickness (TOXE) penalty and without having to rely on adjusting gate terminal film thicknesses.

With MOSFETs (metal oxide semiconductor field effect transistors), an applied voltage to the gate electrode controls the amount of charge close to the silicon surface, which in turn, controls conductivity in the transistor channel, for example, allowing it to be turned on and off. The required gate voltage to turn on a MOS transistor (to form the inversion channel), the threshold voltage Vt, is defined by the work functions of the transistor channel semiconductor and the gate electrode and by additional charges at the transistor channel-dielectric interface and distributed charges through the dielectric. Ideally, the work function difference between channel/dielectric material and gate electrode should be small if a low threshold voltage is desired. For P-type MOS transistors, a higher work function (WF) results in a lower threshold, while for NMOS transistors, a lower WF results in a lower threshold.

With previous design generations, it was easier to match and control gate work functions with the pervasive use of polysilicon as a gate material and silicon oxide as the primary dielectric material. However, with contemporary and future technologies using much smaller process feature sizes (e.g., FinFET and gate-all-around (GAA) approaches with feature sizes near or below 5 nM, so-called high K dielectrics such as hafnium oxides have been used, resulting in the need for different gate materials such as metallic nitrides for among other reasons, to achieve favorable work function characteristics.

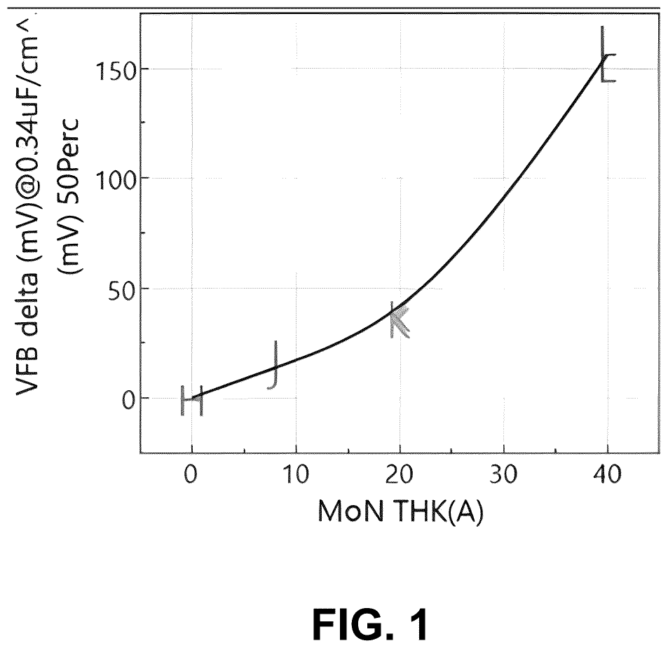

FIG. 1 is a graph showing a relationship between WF and gate material thickness for a PMOS example. In this graph, a relationship between WF (proportional to the indicated VFB, flatband voltage, delta) and the thickness of an MoN layer, a layer in the PMOS gate WF stack is shown. As can be seen, the WF, and thus, the threshold voltage level, can be tuned by adjusting the thickness of the gate layer. This has been an effective way to tune threshold voltage for the various transistor varieties used with integrated circuits (ICs). Unfortunately, this correlation between the thickness of the metal nitride layer and the flat band voltages of the gate's WF stack breaks down for more advanced process nodes. For example, with gate-all-around (GAA) structures where space between adjacent nano channels (wires, sheets, ribbons) is limited (e.g., less than 20 A) and conformal coverage is not always easily achievable, gate thicknesses may be limited and thus not amenable to adjustment for sufficient WF tuning. Accordingly, it would be desirable to be able to tune device threshold voltages by adjusting (e.g., boosting) gate stack work functions without having to increase gate WF stack thicknesses and at the same time, not incur intolerable leakage penalties.

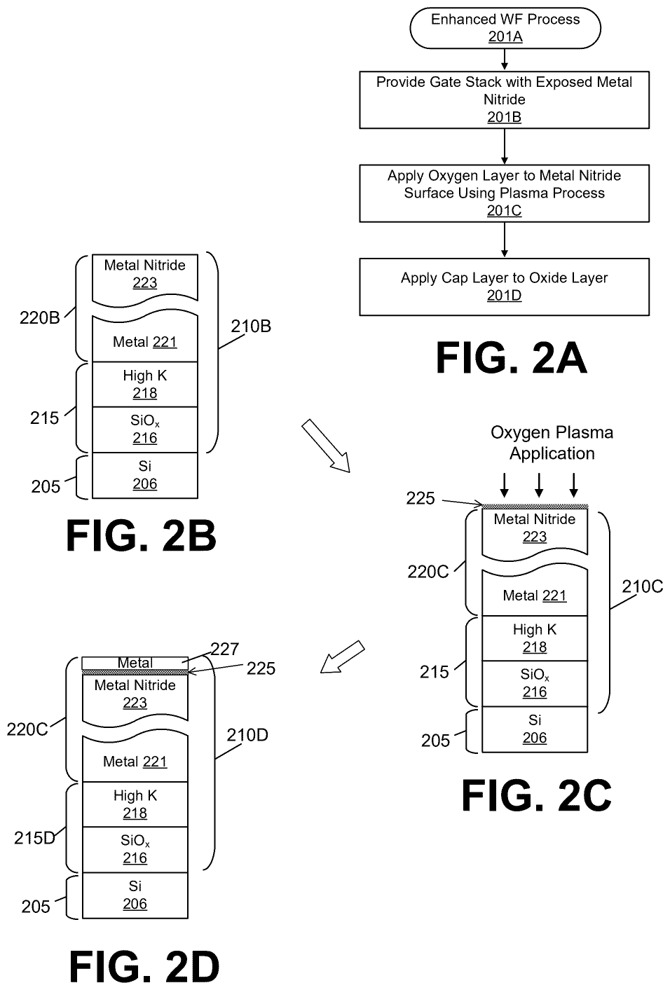

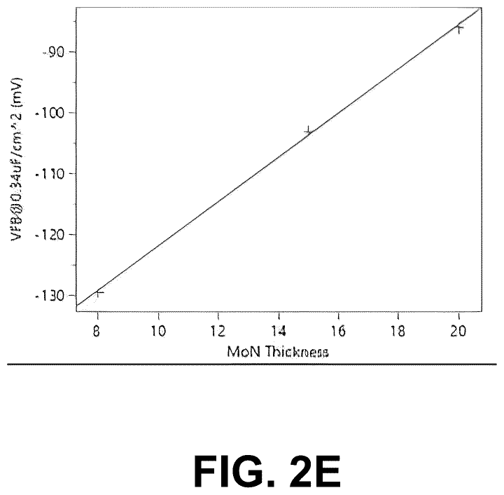

FIG. 2A is a flow diagram showing a process for generating a PMOS transistor gate with an enhanced work function in accordance with some embodiments. FIGS. 2B-2D are cross-sectional schematic diagrams illustrating the formed gate at different stages in accordance with some embodiments.

At 201B (FIG. 2B), a portion of a P-type MOS transistor having a gate stack with an exposed metal nitride (molybdenum nitride, e.g., MON) is shown. The transistor section includes a channel portion 205 and a gate 210B disposed atop the channel. The channel comprises a doped silicon material 212 such as an N-type dopant since the transistor is a PMOS transistor in this example.

The gate 210 includes a dielectric 215 sandwiched between the channel 205 and a gate terminal stack 220. The gate dielectric includes a silicon oxide layer 216 and a high K material layer 218 atop the silicon oxide layer as is shown. A high-K material may be any suitable material including but not limited to Ta₂O₅, Al₂O₃, ZrO₂, PZT, and hafnium nitrides or oxides such as HfO₂. Moreover, the gate dielectric and terminal layers may be formed using any suitable manner such as through a gate-first or a gate-last (a.k.a. replacement) approach.

The gate terminal stack 220 (also referred to herein as a work function, WF, stack) comprises one or more metallic layers 221, which may include metallic nitrides and/or other metals, and an upper metallic nitride layer 223. Metallic nitrides can include but are not limited to molybdenum nitride, titanium nitride, tungsten nitride, and vanadium nitride.

Next, at 201C (FIG. 2C), an oxygen plasma layer 225 is deposited into, or atop, the metal nitride layer. Note that the transistor is actually part of a much larger wafer with billions if not trillions of transistors being fabricated on the wafer, which is disposed in a chamber for select plasma treatment. For example, a high-pressure radical rich plasma process that avoids ion-induced damage may be employed. Natural oxidation, which results in O₃ oxidation, should be avoided. It is desirable to achieve an oxidation layer of a few monolayers (e.g., 1-3 A) into the metallic nitride surface having tight O_{2(dioxides)}, rather than O₃, bonds with the metal.

In some embodiments, with a molybdenum nitride surface layer, a controlled radical rich, low energy plasma oxidation using an He/O₂ plasma mixture may be used. For example, an indirect ionizing technique such as a penning ionization process or other methods such as an ICP (inductively coupled plasma) method may be employed. With such techniques, a desired MOO₂, rather than MoO₃, at 1 to 3 A may be attained. Utilized plasma treatment conditions (e.g., gas flow ratios, pressure, power, time, temperature) should be tuned for the specifically used exposed metallic nitride layer to sufficiently limit oxidation to the surface and not affect the rest of the terminal stack. For example, if an excessive oxidizing treatment is applied to a MoN surface, it can damage the underlying dielectric layer, resulting in effective dielectric thickness (TOXE) penalties. It could also increase nucleation delays or cause longer incubation times of subsequently deposited films (e.g., other terminal stack or photolithography process layers), which can inherently modify the interfacial layer and/or negatively impact the process flow. Of course, optimal parameters for a given implementation will depend on the utilized materials, plasma methodology and chamber capabilities, as well as on the desired wF stack properties.

Next, at 201D, a conductive cap layer 227 is deposited onto the oxidation layer. Among other things, the cap layer is used to protect the oxidation layer and underlying metallic nitride from unwanted contaminating oxidation. Any suitable material may be used for this cap layer, although it should be resistant to corrosion and amenable to HVM (high volume manufacturing) deposition processes. Suitable materials may include but are not limited to ruthenium, cobalt, molybdenum, platinum, rhodium, palladium, osmium, iridium and different metallic alloys such as WN, TiN, or TaN,

Experimentation was performed on a gate having a MoN top layer with oxidation achieved through a penning ionization plasma process as described above. improved work function characteristics were observed using three different MoN film (layer) thicknesses (8A, 15A, and 20 A) as shown in the below table.

| | 8 A MoN | 15 A MoN | 20 A MoN |
|---|---|---|---|
| VFB@0.34 uF/cm\hat{ }2 | Thickness | Thickness | Thickness |
| w/o Oxidation | −184 | −156 | −165 |
| Oxidation - He/O2 | −129.5 | −103 | −86 |
| (Δ)Improvement | ~55 | ~55 | ~80 |

With reference to FIG. 2E, it was discovered that within the tested thickness ranges, the flatband voltage (VFB@0.34 uF/cm\hat{ }2), which indicates the strength of the WF material, scales linearly with MoN thickness.

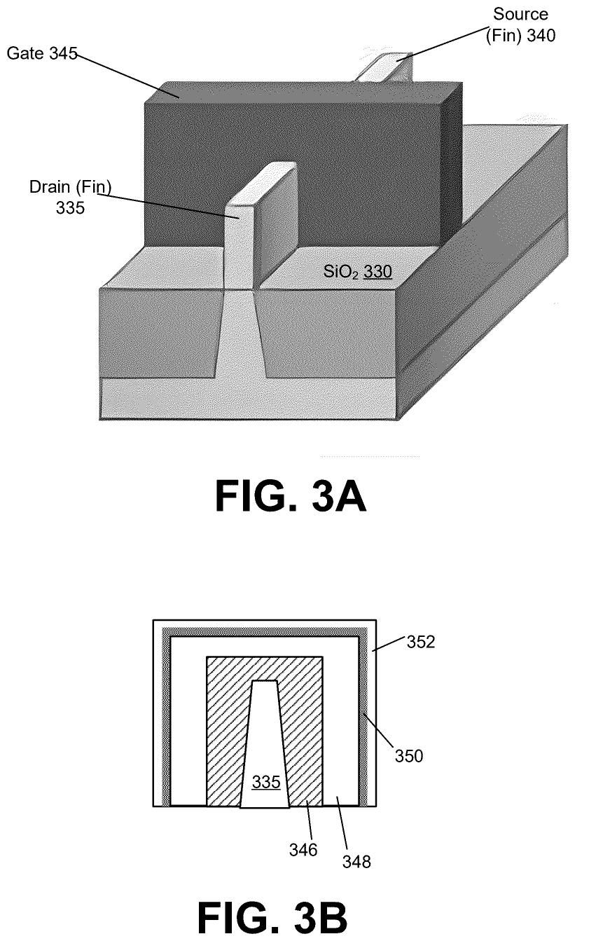

FIG. 3A is a perspective view of a FinFET transistor structure using a WF enhanced gate terminal in accordance with some embodiments. The transistor includes a substrate, upon which the active transistor features are formed. Included are a “fin”, which defines the channel with a drain 335 and source 340 on either side of the channel. It also has a gate 345 that surrounds the channel on three sides as shown.

FIG. 3B is a cross-sectional diagram showing a gate structure for the FinFET of FIG. 3A in accordance with some embodiments. The gate includes a dielectric 346 surrounding the fin. It also includes a terminal stack 348 that includes at least one metal nitride at its outer surface, which has a plasma deposited oxidation film 350 formed about it. Also included is a protective cap layer 352 formed from an anti-corrosive material such as ruthenium.

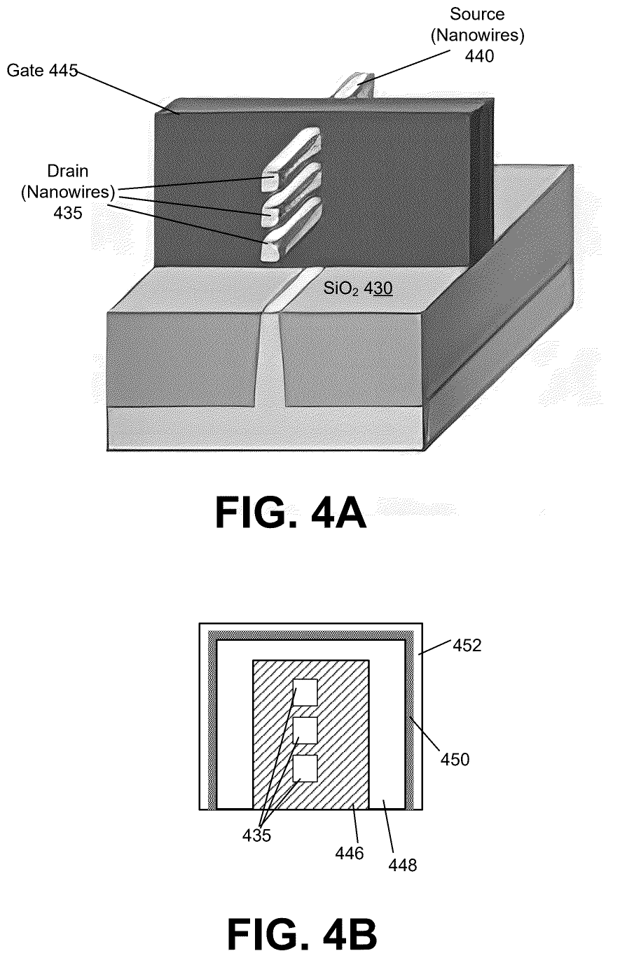

FIG. 4A is a perspective view of a gate-all-around (GAA) nanowire transistor structure using a WF enhanced gate terminal in accordance with some embodiments. The transistor includes a substrate 430, upon which the active transistor features are formed. Included are nanowires, which define the channels with drains 435 and sources 440 on either side of the nanowire channels. (Note that the drains would be coupled to a common drain terminal as would the sources be coupled to a common source terminal.) It also has a gate 445 that encompasses each of the nanowire channels as shown.

FIG. 4B is a cross-sectional diagram showing a gate structure for the nanowire GAA transistor of FIG. 4A in accordance with some embodiments. The gate includes a dielectric 446 surrounding the nanowire channels. It also includes a terminal stack 448 that includes at least one metal nitride at its outer surface, which has a plasma deposited oxidation film 450 formed about it. Also included is a protective cap layer 452 formed from an anti-corrosive material such as ruthenium or the like.

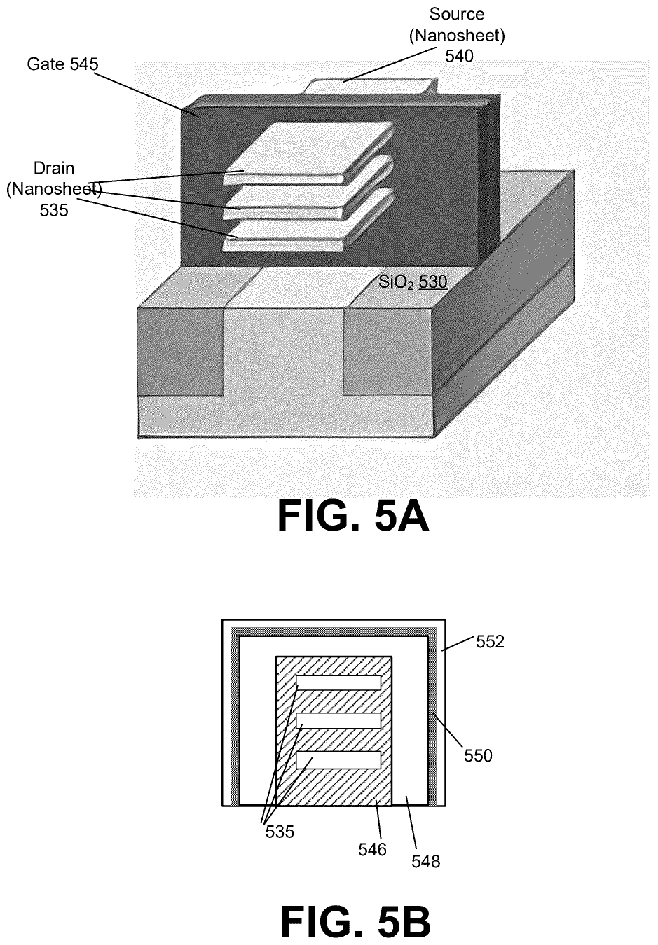

FIG. 5A is a perspective view of a GAA nanosheet (or nanoribbon) transistor structure using a WF enhanced gate terminal in accordance with some embodiments. The transistor includes a substrate 530, upon which the active transistor features are formed. Included are nanosheets, which define the channels having drains 535 and sources 540 on either side of the nanosheet channels. (Note that the drains would be coupled to a common drain terminal as would the sources be coupled to a common source terminal.) It also has a gate 545 that encompasses each of the nanosheet channels as shown.

FIG. 5B is a cross-sectional diagram showing a gate structure for the nanosheet GAA transistor of FIG. 5A in accordance with some embodiments. The gate includes a dielectric 546 surrounding the nanosheet channels. It also includes a terminal stack 548 that includes at least one metal nitride at its outer surface, which has a plasma deposited oxidation film 550 formed about it. Also included is a protective cap layer 552 formed from an anti-corrosive material such as ruthenium or the like.

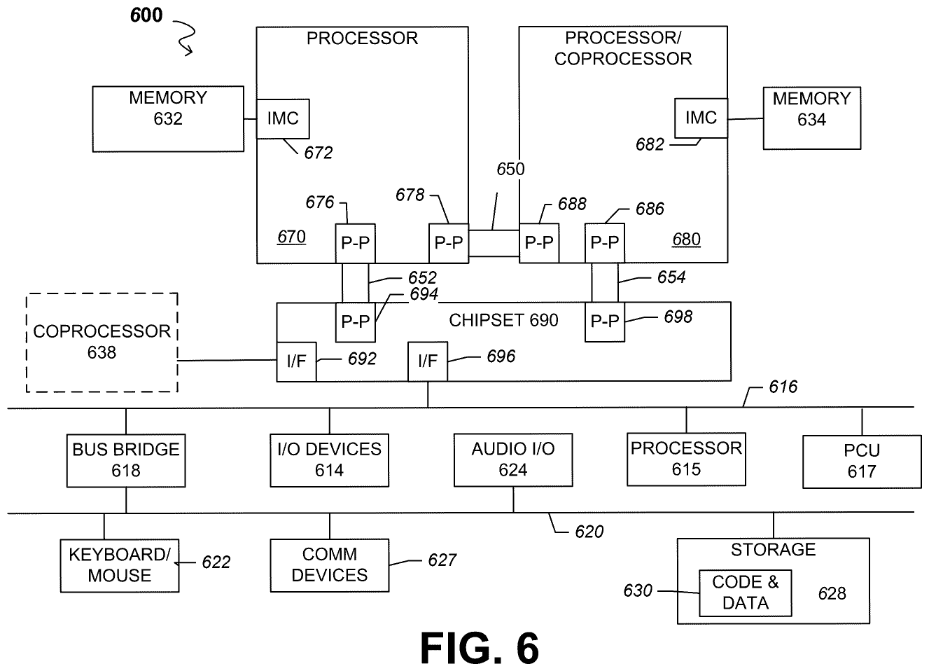

FIG. 6 illustrates an example computing system in accordance with some embodiments. The circuits used to implement the various system blocks may be implemented with transistors including PMOS transistors with oxidized gate terminals as described herein. System 600 is an interfaced system and includes a plurality of processors including a first processor 670 and a second processor 680 coupled via an interface 650 such as a point-to-point (P-P) interconnect, a fabric, and/or bus. In some examples, the first processor 670 and the second processor 680 are homogeneous. In some examples, first processor 670 and the second processor 680 are heterogenous. Though the example system 600 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 670 and 680 are shown including integrated memory controller (IMC) circuitry 672 and 682, respectively. Processor 670 also includes interface circuits 676 and 678, along with core sets. Similarly, second processor 680 includes interface circuits 686 and 688, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 670, 680 may exchange information via the interface 650 using interface circuits 678, 688. IMCs 672 and 682 couple the processors 670, 680 to respective memories, namely a memory 632 and a memory 634, which may be portions of main memory locally attached to the respective processors.

Processors 670, 680 may each exchange information with a network interface (NW I/F) 690 via individual interfaces 652, 654 using interface circuits 676, 694, 686, 698. The network interface 690 (e.g., one or more of an interconnect, bus, and/or fabric, and in some examples is a chipset) may optionally exchange information with a coprocessor 638 via an interface circuit 692. In some examples, the coprocessor 638 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 670, 680 or outside of both processors, yet connected with the processors via an interface such as P-P interconnect, such that either or both processors' local cache information may be stored in the shared cache if a processor is placed into a low power mode.

Network interface 690 may be coupled to a first interface 616 via interface circuit 696. In some examples, first interface 616 may be an interface such as a Peripheral Component Interconnect (PCI) interconnect, a PCI Express interconnect, or another I/O interconnect. In some examples, first interface 616 is coupled to a power control unit (PCU) 617, which may include circuitry, software, and/or firmware to perform power management operations with regard to the processors 670, 680 and/or co-processor 638. PCU 617 provides control information to one or more voltage regulators (not shown) to cause the voltage regulator(s) to generate the appropriate regulated voltage(s). PCU 617 also provides control information to control the operating voltage generated. In various examples, PCU 617 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 617 is illustrated as being present as logic separate from the processor 670 and/or processor 680. In other cases, PCU 617 may execute on a given one or more of cores (not shown) of processor 670 or 680. In some cases, PCU 617 may be implemented as a microcontroller (dedicated or general-purpose) or other control logic configured to execute its own dedicated power management code, sometimes referred to as P-code. In yet other examples, power management operations to be performed by PCU 617 may be implemented externally to a processor, such as by way of a separate power management integrated circuit (PMIC) or another component external to the processor. In yet other examples, power management operations to be performed by PCU 617 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 614 may be coupled to first interface 616, along with a bus bridge 618 which couples first interface 616 to a second interface 620. In some examples, one or more additional processor(s) 615, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 616. In some examples, second interface 620 may be a low pin count (LPC) interface. Various devices may be coupled to second interface 620 including, for example, a keyboard and/or mouse 622, communication devices 627 and storage circuitry 628. Storage circuitry 628 may be one or more non-transitory machine-readable storage media as described below, such as a disk drive or other mass storage device which may include instructions/code and data 630 and may implement the storage in some examples. Further, an audio I/O 624 may be coupled to second interface 620. Note that other architectures than the point-to-point architecture described above are possible. For example, instead of the point-to-point architecture, a system such as multiprocessor system 600 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

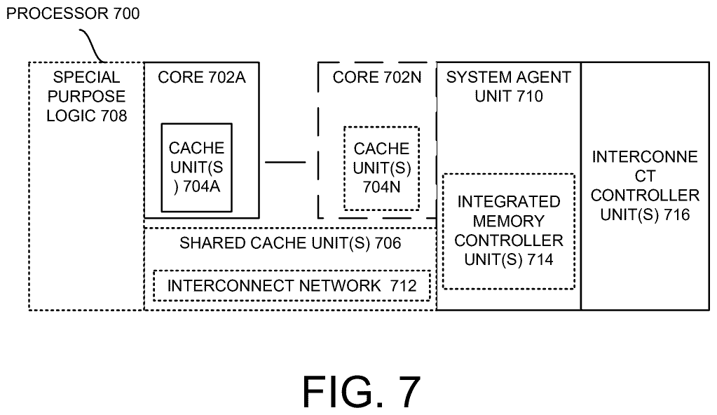

FIG. 7 illustrates a block diagram of an example processor and/or SoC 700 that may have one or more cores and an integrated memory controller in accordance with some embodiments. The solid lined boxes illustrate a processor 700 with a single core 702(A), system agent unit circuitry 710, and a set of one or more interface controller unit(s) circuitry 716, while the optional addition of the dashed lined boxes illustrates an alternative processor 700 with multiple cores 702(A)-(N), a set of one or more integrated memory controller unit(s) circuitry 714 in the system agent unit circuitry 710, and special purpose logic 708, as well as a set of one or more interface controller units circuitry 716. Note that the processor 700 may be one of the processors 670 or 680, or co-processor 638 or 615 of FIG. 6.

Thus, different implementations of the processor 700 may include: 1) a CPU with the special purpose logic 708 being integrated graphics and/or scientific (throughput) logic (which may include one or more cores, not shown), and the cores 702(A)-(N) being one or more general purpose cores (e.g., general purpose in-order cores, general purpose out-of-order cores, or a combination of the two); 2) a coprocessor with the cores 702(A)-(N) being a large number of special purpose cores intended primarily for graphics and/or scientific (throughput); and 3) a coprocessor with the cores 702(A)-(N) being a large number of general purpose in-order cores. Thus, the processor 700 may be a general-purpose processor, coprocessor or special-purpose processor, such as, for example, a network or communication processor, compression engine, graphics processor, GPGPU (general purpose graphics processing unit), a high throughput many integrated core (MIC) coprocessor (including 30 or more cores), embedded processor, or the like. The processor may be implemented on one or more chips. The processor 700 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 704(A)-(N) within the cores 702(A)-(N), a set of one or more shared cache unit(s) circuitry 706, and external memory (not shown) coupled to the set of integrated memory controller unit(s) circuitry 714. The set of one or more shared cache unit(s) circuitry 706 may include one or more mid-level caches, such as level 2 (L2), level 3 (L3), level 4 (L4), or other levels of cache, such as a last level cache (LLC), and/or combinations thereof. While in some examples interface network circuitry 712 (e.g., a ring interconnect) interfaces the special purpose logic 708 (e.g., integrated graphics logic), the set of shared cache unit(s) circuitry 706, and the system agent unit circuitry 710, alternative examples use any number of well-known techniques for interfacing such units. In some examples, coherency is maintained between one or more of the shared cache unit(s) circuitry 706 and cores 702(A)-(N). In some examples, interface controller units circuitry 716 couple the cores 702 to one or more other devices 718 such as one or more I/O devices, storage, one or more communication devices (e.g., wireless networking, wired networking, etc.), etc.

In some examples, one or more of the cores 702(A)-(N) are capable of multi-threading. The system agent unit circuitry 710 includes those components coordinating and operating cores 702(A)-(N). The system agent unit circuitry 710 may include, for example, power control unit (PCU) circuitry and/or display unit circuitry (not shown). The PCU may be or may include logic and components needed for regulating the power state of the cores 702(A)-(N) and/or the special purpose logic 708 (e.g., integrated graphics logic). The display unit circuitry is for driving one or more externally connected displays.

The cores 702(A)-(N) may be homogenous in terms of instruction set architecture (ISA). Alternatively, the cores 702(A)-(N) may be heterogeneous in terms of ISA; that is, a subset of the cores 702(A)-(N) may be capable of executing an ISA, while other cores may be capable of executing only a subset of that ISA or another ISA.

Illustrative examples of the technologies disclosed herein are provided below. An embodiment of the technologies may include any one or more, and any compatible combination of, the examples described below.

Example 1 is a gate apparatus for a transistor. The apparatus includes a dielectric stack, having at least one dielectric layer; a terminal stack, and an oxidation layer. The terminal stack is disposed on the dielectric stack, and the terminal stack has at least one layer including a metal nitride layer with an outer surface. The oxidation layer is formed on the metal nitride layer outer surface and comprises at least 50% metallic-dioxide.

Example 2 includes the subject matter of example 1, and wherein the metallic nitride is molybdenum nitride.

Example 3 includes the subject matter of any of examples 1-2, and wherein the metallic nitride includes a metal selected from a group of metals consisting of molybdenum, titanium, tungsten, and vanadium.

Example 4 includes the subject matter of any of examples 1-3, and wherein the oxidation layer is less than 3 A in thickness.

Example 5 includes the subject matter of any of examples 1-4, and wherein the transistor is a gate-all-around (GAA) transistor.

Example 6 includes the subject matter of any of examples 1-5, and wherein the GAA transistor has multiple nanosheets within the dielectric stack.

Example 7 includes the subject matter of any of examples 1-6, and wherein the dielectric stack comprises a hafnium oxide layer.

Example 8 includes the subject matter of any of examples 1-7, and wherein the terminal stack includes a conductive cap layer disposed on the oxidation layer.

Example 9 includes the subject matter of any of examples 1-8, and wherein the conductive cap layer is formed from a platinum group metal.

Example 10 is a circuit that has a plurality of P-type transistors each comprising a gate in accordance with the gate apparatus of any of claims 1-9.

Example 11 is a processor with a circuit in accordance with the circuit of example 10.

Example 12 is a process for making a transistor gate. The process includes providing a substrate and a dielectric stack formed about a channel. It also includes depositing a gate terminal stack about the dielectric stack, the gate terminal stack having at least one metallic nitride having an exposed surface. It further includes depositing a film of a dioxide rich oxide into the outer surface using an oxygen containing plasma.

Example 13 includes the subject matter of example 12, and wherein the oxygen containing plasma is a mixture of helium and oxygen.

Example 14 includes the subject matter of any of examples 12-13, and wherein the metallic nitride is molybdenum nitride.

Example 15 includes the subject matter of any of examples 12-14, and wherein the metallic nitride includes a metal selected from a group of metals consisting of molybdenum, titanium, tungsten, and vanadium.

Example 16 includes the subject matter of any of examples 12-15, and wherein the oxidation layer is less than 3 A in thickness.

Example 17 includes the subject matter of any of examples 12-16, and wherein the gate is part of a P-type gate-all-around (GAA) transistor.

Example 18 includes the subject matter of any of examples 12-17, and wherein the GAA transistor has multiple nanosheets within the dielectric stack.

Example 19 includes the subject matter of any of examples 12-18, and wherein the dielectric stack comprises a hafnium oxide layer.

Example 20 includes the subject matter of any of examples 12-19, and further comprising depositing a conductive cap layer onto the oxidation layer.

Example 21 includes the subject matter of any of examples 12-20, and wherein a penning ionization process is used to generate ions for the plasma.

Example 22 includes the subject matter of any of examples 12-21, and wherein the oxygen containing plasma is a radical rich plasma.

Example 23 is an integrated circuit having a plurality of transistors with gates formed in accordance with the process of any of examples 12-22.

Example 24 is a computing system that includes a memory and a processor. The processor is coupled to the memory. The processor has circuitry formed from a plurality of P-type metal oxide semiconductor (MOS) transistors each having a gate structure that includes a dielectric stack having at least one dielectric layer; and a terminal stack disposed on the dielectric stack. The terminal has at least one layer including a metal nitride layer with an outer surface. There is also an oxidation layer formed on the metal nitride layer outer surface, the oxidation layer comprising at least 50% metallic-dioxide.

Example 25 includes the subject matter of example 24, and wherein the metallic nitride is molybdenum nitride.

Example 26 includes the subject matter of any of examples 24-25, and wherein the metallic nitride includes a metal selected from a group of metals consisting of molybdenum, titanium, tungsten, and vanadium.

Example 27 includes the subject matter of any of examples 24-26, and wherein the oxidation layer is less than 3 A in thickness.

Example 28 includes the subject matter of any of examples 24-27, and wherein the transistor is a gate-all-around (GAA) transistor.

Example 29 includes the subject matter of any of examples 24-28, and wherein the GAA transistor has multiple nanosheets within the dielectric stack.

Example 30 includes the subject matter of any of examples 24-29, and wherein the dielectric stack comprises a hafnium oxide layer.

Example 31 includes the subject matter of any of examples 24-30, and wherein the terminal stack includes a conductive cap layer disposed on the oxidation layer.

Example 32 includes the subject matter of any of examples 24-31, and wherein the conductive cap layer is formed from a platinum group metal.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]” depending on the context. As defined herein, the term “responsive to” means responding or reacting readily to an action or event. Thus, if a second action is performed “responsive to” a first action, there is a causal relationship between an occurrence of the first action and an occurrence of the second action. The term “responsive to” indicates the causal relationship.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth. It should be appreciated that a logical processor, on the other hand, is a processing abstraction associated with a core, for example when one or more SMT cores are being used such that multiple logical processors may be associated with a given core, for example, in the context of core thread assignment.

It should be appreciated that a processor or processor system may be implemented in various different manners. For example, it may be implemented on a single die, multiple dies (dielets, chiplets), one or more dies in a common package, or one or more dies in multiple packages. Along these lines, some of these blocks may be located separately on different dies or together on two or more different dies.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. A gate apparatus for a transistor, comprising:
a dielectric stack having at least one dielectric layer; and
a terminal stack disposed on the dielectric stack, the terminal stack having;
at least one layer including a metal nitride layer with an outer surface, and
an oxidation layer formed on the metal nitride layer outer surface, the oxidation layer comprising at least 50% metallic-dioxide.

2. The apparatus of claim 1, wherein the metallic nitride includes a metal selected from a group of metals consisting of molybdenum, titanium, tungsten, and vanadium.

3. The apparatus of claim 1, wherein the oxidation layer is less than 3 A in thickness.

4. The apparatus of claim 1, wherein the transistor is a gate-all-around (GAA) transistor.

5. The apparatus of claim 1, wherein the terminal stack includes a conductive cap layer disposed on the oxidation layer.

6. The apparatus of claim 5, wherein the conductive cap layer is formed from a platinum group metal.

7. A circuit having a plurality of P-type transistors each comprising a gate in accordance with the gate apparatus of claim 1.

8. A process for making a transistor gate, comprising:
providing a substrate and a dielectric stack formed about a channel,
depositing a gate terminal stack about the dielectric stack, the gate terminal stack having at least one metallic nitride having an exposed surface; and
depositing a film of a dioxide rich oxide into the outer surface using an oxygen containing plasma.

9. The process of claim 8, wherein the oxygen containing plasma is a mixture of helium and oxygen.

10. The process of claim 8, wherein the metallic nitride includes a metal selected from a group of metals consisting of molybdenum, titanium, tungsten, and vanadium.

11. The process of claim 8, wherein the oxidation layer is less than 3 A in thickness.

12. The process of claim 8, wherein the gate is part of a P-type gate-all-around (GAA) transistor.

13. The process of claim 8, wherein a penning ionization process is used to generate ions for the plasma.

14. The process of claim 8, wherein the oxygen containing plasma is a radical rich oxygen containing plasma.

15. An integrated circuit having a plurality of transistors with gates formed in accordance with the process of claim 8.

16. A computing system, comprising:
a memory; and
a processor coupled to the memory, the processor having circuitry formed from a plurality of P-type metal oxide semiconductor (MOS) transistors each having a gate structure including:
a dielectric stack having at least one dielectric layer; and
a terminal stack disposed on the dielectric stack, the terminal stack having:
at least one layer including a metal nitride layer with an outer surface, and
an oxidation layer formed on the metal nitride layer outer surface, the oxidation layer comprising at least 50% metallic-dioxide.

17. The apparatus of claim 16, wherein the metallic nitride is molybdenum nitride.

18. The apparatus of claim 16, wherein the metallic nitride includes a metal selected from a group of metals consisting of molybdenum, titanium, tungsten, and vanadium.

19. The apparatus of claim 16, wherein the oxidation layer is less than 3 A in thickness.

20. The apparatus of claim 16, wherein the terminal stack includes a conductive cap layer disposed on the oxidation layer.
